(19) United States
(12) Patent Application Publication
(10) Pub. No.: US 2025/0338695 A1
(43) Pub. Date: Oct. 30, 2025

(54) ELECTRONIC DEVICE AND MANUFACTURING METHOD OF ELECTRONIC DEVICE

(71) Applicant: Innolux Corporation, Miaoli County (TW)

(72) Inventors: Yu-Jun Peng, Miaoli County (TW); Yi-Ching Huang, Miaoli County (TW); Chiung-Chieh Kuo, Miaoli County (TW); Kuan-Hung Kuo, Miaoli County (TW)

(73) Assignee: Innolux Corporation, Miaoli County (TW)

(21) Appl. No.: 19/086,156

(22) Filed: Mar. 21, 2025

(30) Foreign Application Priority Data
Apr. 26, 2024 (CN) 202410515255.5

(51) Int. Cl. H10H 29/855; H10H 29/01; H10H 29/85

(52) U.S. Cl. CPC H10H 29/8552; H10H 29/012; H10H 29/0363; H10H 29/857

(57) ABSTRACT

An electronic device, including a circuit substrate, a light-absorbing layer, and an electronic component, is provided. The light-absorbing layer is disposed on the circuit substrate, and the light-absorbing layer includes an opening. The electronic component is disposed in the opening and is electrically connected to the circuit substrate. In a cross-sectional view of the electronic device, a profile of a sidewall of the opening has at least one arc-shaped edge, and an inclination angle between an extension line of the sidewall of the opening and a horizontal line is between 75 degrees and 105 degrees.

### CROSS-REFERENCE TO RELATED APPLICATION

This application claims the priority benefit of China application serial no. 202410515255.5, filed on Apr. 26, 2024. The entirety of the above-mentioned patent application is hereby incorporated by reference herein and made a part of this specification.

### BACKGROUND

### Technical Field

The disclosure relates to an electronic device and a manufacturing method of the electronic device.

### Description of Related Art

In the conventional electronic device, the reflectivity is reduced through setting a light-shielding layer, and a placement space of an electronic component is defined through setting a pixel defining layer. If the light-shielding layer and the pixel defining layer can be integrated into one layer (hereinafter referred to as a light-absorbing layer), the number of processes for forming the electronic device can be reduced, thereby improving the process efficiency of the electronic device and/or reducing the process cost of the electronic device.

However, during the process of forming the light-absorbing layer, the characteristics of the relatively thick thickness and/or the relatively low reflectivity causes the photosensitivity of a bottom portion of the light-absorbing layer to be relatively poor. Therefore, the formed light-absorbing layer has an obvious inverted trapezoidal structure, which reduces the reliability of the electronic device due to the unstable structure.

### SUMMARY

The disclosure provides an electronic device, which has reduced manufacturing costs and improved reliability.

An electronic device provided according to some embodiments of the disclosure includes a circuit substrate, a light-absorbing layer, and an electronic component. The light-absorbing layer is disposed on the circuit substrate, and the light-absorbing layer includes an opening. The electronic component is disposed in the opening and is electrically connected to the circuit substrate. In a cross-sectional view of the electronic device, a profile of a sidewall of the opening has at least one arc-shaped edge, and an inclination angle between an extension line of the sidewall of the opening and a horizontal line is between 75 degrees and 105 degrees.

The disclosure also provides a method manufacturing of an electronic device, which can improve process efficiency and improve the reliability of the formed electronic device.

A method manufacturing of an electronic device provided according to some embodiments of the disclosure includes the following steps. A circuit substrate is provided. A photoresist is coated on the circuit substrate. A first optical eigenvalue of the photoresist before exposure is measured. The photoresist is exposed. A second optical eigenvalue of the photoresist after exposure is measured. The photoresist is patterned, so that the photoresist forms an opening. A time for patterning the photoresist is adjusted according to a difference between the first optical eigenvalue and the second optical eigenvalue.

Based on the above, in the electronic device and the manufacturing method thereof provided by the disclosure, the light-absorbing layer with relatively low reflectivity and used to define a placement space of the electronic component may be formed using a relatively small number of processes, which can improve the process efficiency of the electronic device provided by the disclosure and/or reduce the process cost of the electronic device provided by the disclosure. Furthermore, the light-absorbing layer in the electronic device provided by the disclosure can still maintain a structure with a relatively stable shape while having a desired thickness (the inclination angle between the extension line of the sidewall of the opening and the horizontal line is between 75 degrees and 105 degrees), thereby improving the reliability of the electronic device provided by the disclosure.

### BRIEF DESCRIPTION OF THE DRAWINGS

FIG. 1 is a partial cross-sectional schematic view of an electronic device according to a first embodiment of the disclosure.

FIG. 2A is an enlarged top schematic view of the first embodiment of a region R according to FIG. 1.

FIG. 2B is an enlarged top schematic view of a second embodiment of a region R according to FIG. 1.

FIG. 2C is an enlarged top schematic view of a third embodiment of a region R according to FIG. 1.

FIG. 2D is an enlarged top schematic view of a fourth embodiment of a region R according to FIG. 1.

FIG. 2E is an enlarged top schematic view of a fifth embodiment of a region R according to FIG. 1.

FIG. 3 is a partial cross-sectional schematic view of an electronic device according to the second embodiment of the disclosure.

### DESCRIPTION OF THE EMBODIMENTS

Reference will now be made in detail to the exemplary embodiments of the disclosure, examples of the exemplary embodiments are illustrated in the drawings. Wherever possible, the same reference numerals are used in the drawings and the description to refer to the same or similar parts.

The disclosure can be understood by referring to the following detailed description in conjunction with the drawings. It should be noted that in order to facilitate the understanding of the reader and the brevity of the drawings, multiple drawings in the disclosure only depict a part of an electronic device, and specific elements in the drawings are not drawn according to actual scale. In addition, the number and the size of each element in the drawings are for illustration only and are not intended to limit the scope of the disclosure.

Throughout the specification and the appended claims of the disclosure, certain terms may be used to refer to specific elements. It should be understood by persons skilled in the art that electronic device manufacturers may refer to the same element by different names. The disclosure does not intend to distinguish between elements with the same function but different names. In the following specification and claims, terms such as “including”, “containing”, and “having” are open-ended terms, so the terms should be interpreted as “containing but not limited to . . . ”. Therefore, when the terms “including”, “containing”, and/or “having” are used in the description of the disclosure, the terms designate the presence of a corresponding feature, region, step, operation, and/or component, but do not exclude the presence of one or more corresponding features, regions, steps, operations, and/or components.

Directional terms such as “upper”, “lower”, “front”, “rear”, “left”, and “right” mentioned in the disclosure are only directions with reference to the drawings. Therefore, the used directional terms are used to illustrate, but not to limit, the disclosure. In the drawings, each drawing illustrates the general features of a method, a structure, and/or a material used in a specific embodiment. However, the drawings should not be construed to define or limit the scope or nature covered by the embodiments. For example, for clarity, relative sizes, thicknesses, and positions of various film layers, regions, and/or structures may be reduced or enlarged.

When a corresponding component (for example, a film layer or a region) is referred to as being “on another component”, the component may be directly on the other component or there may be another component between the two. On the other hand, when a component is referred to as being “directly on another component”, there is no component between the two. In addition, when a component is referred to as being “on another component”, the two have an upper-lower relationship in the top view direction, and the component may be above or below the other component, and the upper-lower relationship depends on the orientation of the device.

The terms “equal” or “same”, “substantially”, or “roughly” are generally interpreted as within 20% of a given value or range or interpreted as within 10%, 5%, 3%, 2%, 1%, or 0.5% of the given value or range.

Ordinal numbers such as “first” and “second” used in the specification and the claims are used to modify elements, and the terms do not imply and represent that the element(s) have any previous ordinal numbers, nor do they represent the order of a certain element and another element or the order of a manufacturing method. The use of the ordinal numbers is only to clearly distinguish between an element with a certain name and another element with the same name. The claims and the specification may not use the same terms, whereby a first component in the specification may be a second component in the claims.

It should be noted that in the following embodiments, features in several different embodiments may be replaced, recombined, and mixed to complete other embodiments without departing from the spirit of the disclosure. As long as the features of the various embodiments do not violate the spirit of the invention or conflict with each other, the features may be arbitrarily mixed and matched for use.

Electrical connection described in the disclosure may refer to direct connection or indirect connection. In the case of direct connection, terminals of elements on two circuits are directly connected or connected to each other by a conductor segment. In the case of indirect connection, there is a switch, a diode, a capacitor, an inductor, other suitable elements, or a combination of the above elements between the terminals of the elements on the two circuits, but not limited thereto.

In the disclosure, the measurement manner of thickness, length, width, and area may be by adopting an optical microscope, and the thickness may be obtained by measuring a cross-sectional image in an electron microscope, but not limited thereto. In addition, there may be a certain error in any two values or directions for comparison. If a first value is equal to a second value, it implies that there may be an error of about 10% between the first value and the second value. If a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

The electronic device described in the disclosure may be applied to a display device, a light-emitting device, a backlight device, a splicing device, a virtual reality device, an augmented reality device, an antenna device, or a sensing device, but not limited thereto. The electronic device may be a bendable or flexible electronic device. The electronic device may include, for example, liquid crystal, a light-emitting diode, fluorescence, phosphor, other suitable display media, or a combination of the above, but not limited thereto. The display device may be a non-self-luminous display device or a self-luminous display device. The antenna device may be a liquid crystal antenna device or a non-liquid crystal antenna device, and the sensing device may be a sensing device for sensing capacitance, light, heat energy, or ultrasonic waves, but not limited thereto. The electronic device may include, for example, an electronic component such as a passive component and an active component, such as a capacitor, a resistor, an inductor, a diode, and a transistor. The diode may include a light-emitting diode or a photodiode. The light-emitting diodes may include, for example, an organic light-emitting diode (OLED), a mini LED, a micro LED, or a quantum dot LED, but not limited thereto. The splicing device may be, for example, a display splicing device or an antenna splicing device, but not limited thereto. It should be noted that the electronic device may be any permutation and combination of the above, but not limited thereto. In addition, the appearance of the electronic device may be a rectangle, a circle, a polygon, a shape with curved edges, or other suitable shapes. The electronic device may have a peripheral system such as a driving system, a control system, and a light source system to support the display device, the antenna device, a wearable devices (such as including augmented reality or virtual reality), a vehicle-mounted device (such as including a car windshield), or the splicing device.

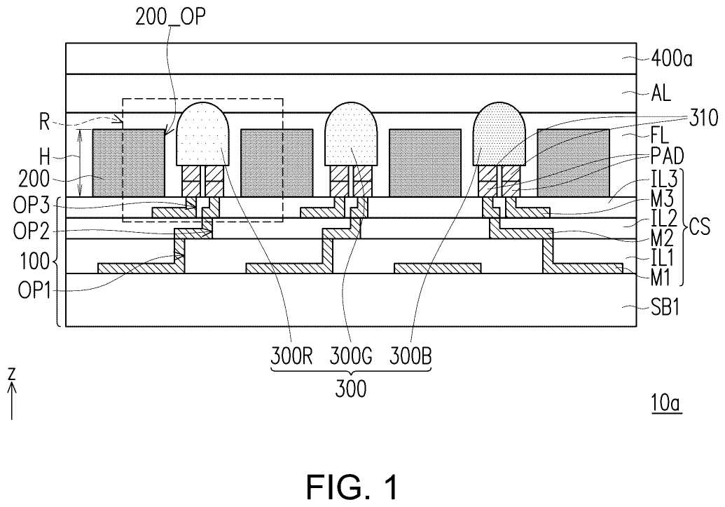

FIG. 1 is a partial cross-sectional schematic view of an electronic device according to a first embodiment of the disclosure.

Please refer to FIG. 1. In the embodiment, an electronic device 10a includes a circuit substrate 100, a light-absorbing layer 200, and an electronic component 300, and may be formed through performing the following steps, but the disclosure is not limited thereto.

In step (1), the circuit substrate 100 is provided. In some embodiments, the circuit substrate 100 may include a substrate SB1 and a connecting structure CS as shown in FIG. 1, but the disclosure is not limited thereto.

The material of the substrate SB1 may be, for example, glass, plastic, or a combination thereof. For example, the material of the substrate SB1 may include quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), other suitable materials, or a combination of the above materials, but the disclosure is not limited thereto

The connecting structure CS is, for example, disposed on the substrate SB1. In some embodiments, the connecting structure CS may be formed through performing a process described below, but the disclosure is not limited thereto.

First, a conductive layer M1 is formed on the substrate SB1. In some embodiments, the conductive layer M1 may be formed through performing the following process. For example, a conductive layer may be first formed on the substrate SB1 through a sputtering process, and the conductive layer M1 may be then formed through a photolithography process. In some embodiments, the material of the conductive layer M1 may include copper or other suitable metals, but the disclosure is not limited thereto.

Next, an insulating layer IL1 is formed on the substrate SB1. In some embodiments, the insulating layer IL1 may be formed through performing the following process. For example, an insulating material layer (not shown) covering the conductive layer M1 may be first formed through performing a physical vapor deposition process or a chemical vapor deposition process, and a patterning process is then performed on the insulating material layer to form the insulating layer IL1 having multiple openings OP1, wherein the openings OP1 expose a part of the conductive layer M1. In some embodiments, the material of the insulating layer IL1 may include an inorganic material (for example, silicon oxide, silicon nitride, or silicon oxynitride), but the disclosure is not limited thereto. In some embodiments, the insulating layer IL1 may be a single-layer structure or a multi-layer structure, but the disclosure is not limited thereto.

In the embodiment, the connecting structure CS may further include a thin film transistor (not shown), wherein the thin film transistor is electrically connected to the conductive layer M1. In detail, in the embodiment, a process of forming the thin film transistor (not shown) may also be performed on the substrate SB1. For example, a buffer layer (not shown), a semiconductor layer (not shown), a first insulating layer (not shown), a gate (not shown), a second insulating layer (not shown), and a source (not shown) and a drain (not shown) may be sequentially formed on the substrate SB1 to form the thin film transistor. In detail, the thin film transistor may include, for example, the gate, the source, the drain, and the semiconductor layer. The gate, for example, partially overlaps with the semiconductor layer in a top view direction z of the electronic device 10a, wherein a region where the semiconductor layer overlaps with the gate may be regarded as a channel region, and the semiconductor layer may have a source region and a drain region located on opposite sides of the channel region. The source and the drain are, for example, separated from each other, and individually electrically connected to the semiconductor layer. In some embodiments, the material of the semiconductor layer may include amorphous silicon, low temperature polycrystalline silicon (LTPS), metal oxide, other suitable materials, or a combination thereof, wherein the metal oxide may include indium gallium zinc oxide (IGZO). In the embodiment, the source and the drain may be individually electrically connected to the source region and the drain region of the semiconductor layer via through holes (not shown) penetrating the first insulating layer and the second insulating layer, but the disclosure is not limited thereto. Although the embodiment uses a top gate thin film transistor as an example, the disclosure is not limited thereto.

In the embodiment, multiple cycles of the above forming method of the conductive layer and the insulating layer may be repeated to form the connecting structure CS as shown in FIG. 1, wherein the connecting structure CS may be used as a wiring layer of the electronic component 300 to provide a required conductive transmission path. For example, as shown in FIG. 1, the connecting structure CS may include the conductive layer M1, the insulating layer IL1 having the openings OP1, a conductive layer M2, an insulating layer IL2 having multiple openings OP2, a conductive layer M3, and an insulating layer IL3 having multiple openings OP3, but the disclosure is not limited thereto. It is worth noting that the material included in each of the conductive layer M2 and the conductive layer M3 is, for example, the same as or similar to the material included in the conductive layer M1, and the material included in each of the insulating layer IL2 and the insulating layer IL3 is, for example, the same as or similar to the material included in the insulating layer IL1.

In step (2), a photoresist is coated on the circuit substrate 100.

In the embodiment, the material of the photoresist includes a photoresist composition and a photochromic material. The photoresist composition may include, for example, a suitable resin (for example, siloxane, acrylic, or polyimide), a photosensitive component, and a solvent to have a light-shielding effect, but the disclosure is not limited thereto. Photochromic materials include, for example, suitable organic compounds. For example, the photochromic material may include aralkyl compound, stilbenes, nitrones, fulgides, spiropyrans, naphthopyrans, spiro-oxazines, quinones, or a combination thereof, but the disclosure is not limited thereto. In some embodiments, the thickness of the photoresist is between 7.5 m and 10.5 m, but the disclosure is not limited thereto.

In step (3), a first optical eigenvalue of the photoresist before exposure is measured.

In some embodiments, the first optical eigenvalue of the photoresist before exposure may be measured through a macroscopic inspection machine, a colorimeter, a spectrometer, or other suitable instruments. After measuring the first optical eigenvalue of the photoresist before exposure, the first optical eigenvalue may be expressed through the CIE 1931 Yxy color space. For example, the chromaticity of the color of the photoresist before exposure may be described through two parameters x and y, and the brightness of the color of the photoresist before exposure may be described through Y in the three-color stimulus values, but the disclosure is not limited thereto. In the embodiment, the first optical eigenvalue is a brightness value (Y), but the disclosure is not limited thereto.

In step (4), the photoresist is exposed.

In some embodiments, the photoresist may be exposed through an exposure machine, wherein the photoresist may be exposed under a condition of an exposure energy being 150 mJ/cm² to 350 mJ/cm², but the disclosure is not limited thereto. Since the photoresist of the embodiment includes the photochromic material, the original color of the photoresist may be changed after exposure, which can reduce cases where a bottom portion of the photoresist receives a weak exposure energy during exposure.

In some embodiments, before exposing the photoresist, a pre-bake process may be performed on the photoresist, but the disclosure is not limited thereto.

In step (5), a second optical eigenvalue of the photoresist after exposure is measured.

In some embodiments, the second optical eigenvalue of the photoresist after exposure may be measured through a macroscopic inspection machine, a colorimeter, a spectrometer, or other suitable instruments. After measuring the second optical eigenvalue of the photoresist after exposure, the second optical eigenvalue may also be expressed through the CIE 1931 Yxy color space, which will not be described again here. In the embodiment, the second optical eigenvalue is the brightness value (Y), but the disclosure is not limited thereto.

In the embodiment, a difference between the first optical eigenvalue and the second optical eigenvalue is related to the exposure energy in the exposure step. In detail, since the photoresist includes the photochromic material, the photoresist may have different chromaticities after being irradiated by light with different exposure energies. Through observing and recording the difference between the first optical eigenvalue and the second optical eigenvalue, the degree of curing of the photoresist may be predicted. Based on this, in the embodiment, through measuring the difference between the brightness value (the first optical eigenvalue) of the photoresist before exposure and the brightness value (the second optical eigenvalue) of the photoresist after exposure, process parameters used in a subsequent process of patterning the photoresist in step (6) may be determined.

In step (6), the photoresist is patterned, so that the photoresist forms an opening.

Patterning the photoresist is performed, for example, through a development process, but the disclosure is not limited thereto. In the embodiment, after performing step (5), the difference between the first optical eigenvalue and the second optical eigenvalue is compared with a preset value to determine the time of the development process. In detail, after measuring the second optical eigenvalue of the photoresist after exposure, a developing solution may be provided to the photoresist using a developing machine, and a break point that is a multiple of the developing time is determined according to the above comparison result. It is worth noting that the definition of the break point is, for example, the time it takes for an unpolymerized portion of the photoresist to be completely removed in the developing solution.

In step (7), the photoresist is cured to form the light-absorbing layer 200.

In the embodiment, a post-bake process is performed on the photoresist to cure the photoresist. For example, the post-bake process may be performed on the photoresist under conditions of the temperature being 200° C. to 300° C. and the time being 30 minutes to 60 minutes, but the disclosure is not limited thereto. In some embodiments, the optical density value of the cured photoresist (light-absorbing layer 200) is between 1.5 and 5. In other embodiments, the optical density value of the cured photoresist (light-absorbing layer 200) is between 2 and 5. That is, the light-absorbing layer 200 of the embodiment can have an improved light-shielding effect.

Based on this, in the embodiment, the developing time of the development process of step (6) and the process conditions in the post-bake process of step (7) may be determined through comparing the difference between the first optical eigenvalue and the second optical eigenvalue with the preset value. For example, the preset value may be, for example, an optical eigenvalue of the black light-absorbing layer 200 with an improved degree of curing after performing the exposure process of step (4), the development process of step (6), and the post-bake process of step (7) on the photoresist. Through comparing a difference value between the first optical eigenvalue and the second optical eigenvalue with the preset value, after performing the exposure process of step (4) on the photoresist with light with different exposure energies, the process conditions in the development process of step (6) and the post-bake process of step (7) may be determined. For example, after the photoresist is irradiated with light with a relatively small exposure energy in the exposure process of step (4), a development process with a relatively short developing time may be later performed in step (6), and a post-bake process with a relatively long curing time may be performed in step (7) to obtain the black light-absorbing layer 200 with an improved degree of curing.

Table 1 below is an example of the process parameters of the photoresist in the exposure process of step (4), the development process of step (6), and the post-bake process of step (7), but the disclosure is not limited thereto.

TABLE 1

| | Difference value | | |
|---|---|---|---|
| | between first | | Process |
| | optical eigenvalue | | conditions |
| Exposure energy | and second optical | Developing | in post-bake |
| (mJ/cm²) | eigenvalue (ΔY) | time (s) | process |
| X − 50, X, X + 50 | >−0.2 | 1.5 times the | 220° C.; 45 |
| | | break point | minutes |
| X + 50 | <−0.2 | 2 times the | 220° C.; 30 |
| | | break point | minutes |

(Note:
X is 250 mJ/cm²)

Based on the above, the developing time in the development process of step (6) and the process conditions in the post-bake process of step (7) may be adjusted through comparing the difference between the first optical eigenvalue and the second optical eigenvalue with the preset value to obtain the light-absorbing layer 200 with substantially the same degree of curing and/or an optical density value between 1.5 and 5 (or 2 and 5).

In step (8), the electronic component 300 is disposed in the opening of the cured photoresist.

Specifically, in the embodiment, the electronic component 300 is disposed in an opening 200_OP of the light-absorbing layer 200. In some embodiments, before disposing the electronic component 300 in the opening 200_OP of the light-absorbing layer 200, a bonding pad PAD may be formed in the opening 200_OP of the light-absorbing layer 200 as a component of the circuit substrate 100, wherein the bonding pad PAD is electrically connected to the conductive layer M3 in the connecting structure CS. Based on this, the electronic component 300 subsequently disposed in the opening 200_OP of the light-absorbing layer 200 may be electrically connected to the connecting structure CS through the bonding pad PAD. In some embodiments, the electronic component 300 includes a red light-emitting diode, a green light-emitting diode, and/or a blue light-emitting diode. For example, in the embodiment, the electronic component 300 includes a red light-emitting diode 300R, a green light-emitting diode 300G, and a blue light-emitting diode 300B, but the disclosure is not limited thereto.

Based on the above, the light-absorbing layer 200 formed in step (2) to step (7) may have both relatively low reflectivity and characteristics for defining the placement space of the electronic component 300, which can improve the process efficiency of the electronic device 10a and/or reduce the process cost of the electronic device 10a.

In step (9), the circuit substrate 100 and an opposing substrate 400a are assembled.

The opposing substrate 400a is, for example, disposed opposing the circuit substrate 100. In detail, in the embodiment, the electronic component 300 on the assembled circuit substrate 100 faces the opposing substrate 400a. In some embodiments, the circuit substrate 100 and the opposing substrate 400a may be assembled through an adhesion layer AL. Specifically, the adhesion layer AL is, for example, disposed between the circuit substrate 100 and the opposing substrate 400a in the top view direction z of the electronic device 10a, so that the circuit substrate 100 and the opposing substrate 400a are adhered to each other.

In addition, in some embodiments, before assembling the circuit substrate 100 and the opposing substrate 400a, a filling layer FL may be formed in the opening of the light-absorbing layer 200. The filling layer FL is, for example, disposed adjacent to or surrounding the electronic component 300, so as to be used, for example, to fix or protect the electronic component 300.

So far, the manufacturing of the electronic device 10a of the embodiment is completed, but the method manufacturing of the electronic device 10a of the disclosure is not limited thereto.

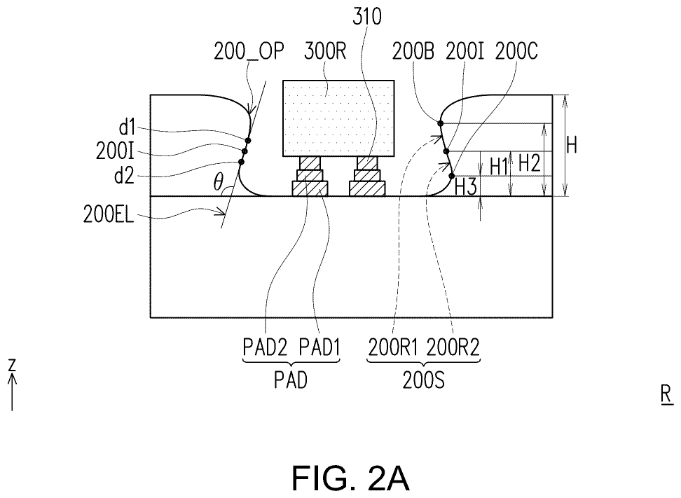

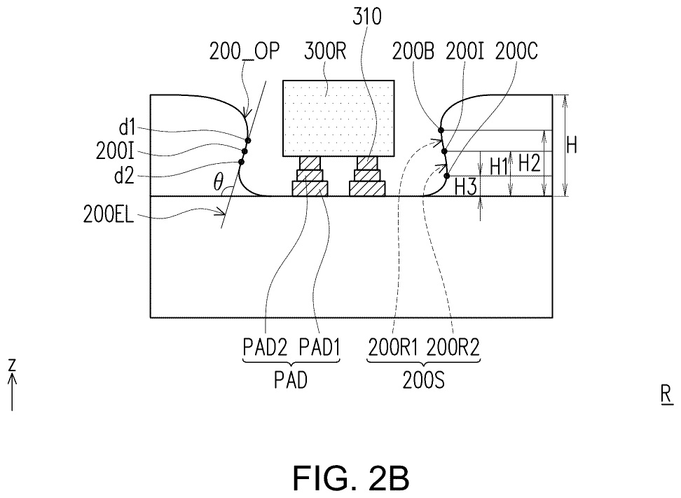

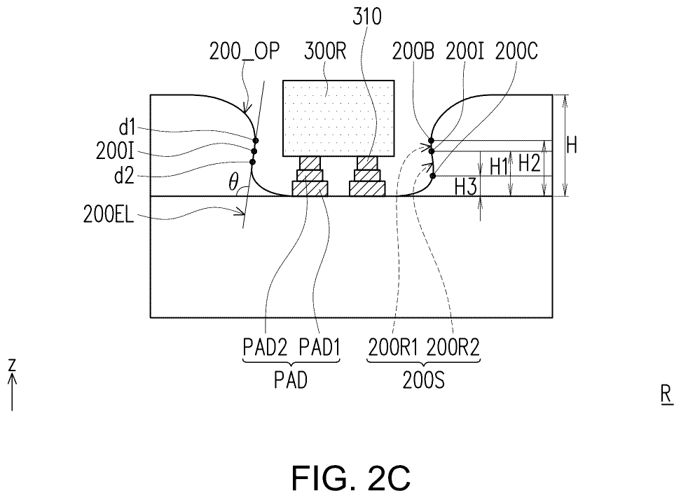

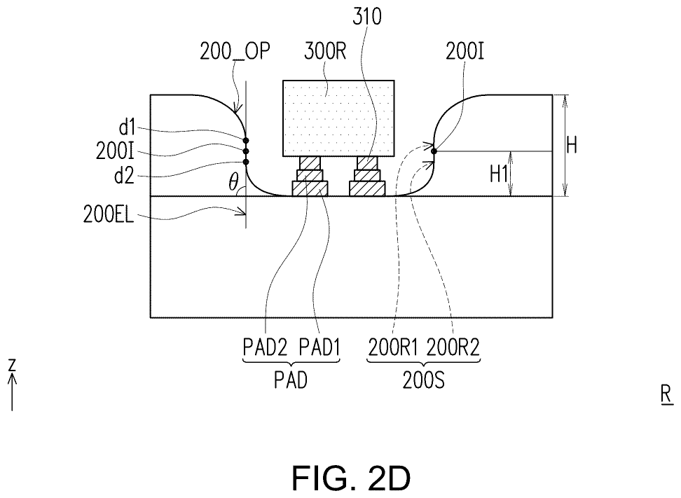

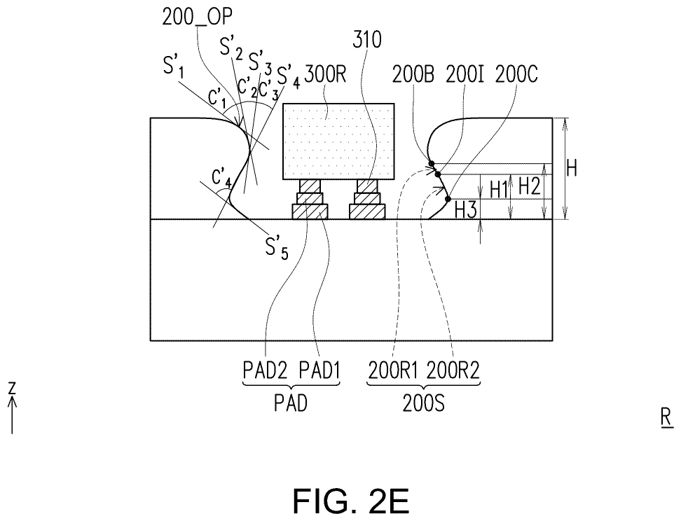

The structure of the electronic device 10a of the embodiment will be briefly introduced below with reference to FIG. 1 and FIG. 2A to FIG. 2E, wherein FIG. 2A to FIG. 2E are individually different embodiments of a region R of the electronic device 10a shown in FIG. 1, but the disclosure is not limited thereto.

Please refer to FIG. 1. In the embodiment, the electronic device 10a has a single-board structure. In detail, the electronic device 10a of the embodiment includes the circuit substrate 100, the light-absorbing layer 200, and the electronic component 300.

The circuit substrate 100 may include, for example, the substrate SB1, the connecting structure CS, and the bonding pad PAD, wherein reference may be made to the above embodiment for the description of the substrate SB1, the connecting structure CS, and the bonding pad PAD, which will not be described again here. It is worth mentioning that the circuit substrate 100 of the embodiment may be a thin film transistor array substrate. In detail, the circuit substrate 100 may also include, for example, the above thin film transistor (not shown), but the disclosure is not limited thereto. In other embodiments, the circuit substrate 100 may be provided with multiple micro integrated circuits (micro ICs), and the electronic component 300 may be driven by the micro ICs.

The light-absorbing layer 200 is, for example, disposed on the circuit substrate 100. In the embodiment, the material of the light-absorbing layer 200 includes a photochromic material, wherein reference may be made to the above embodiment for examples of the photochromic material, which will not be described again here. Through enabling the light-absorbing layer 200 to include the photochromic material, the photosensitivity of a bottom portion of the light-absorbing layer 200 can be enhanced using the discoloration mechanism of the photochromic material during a process of forming the light-absorbing layer 200, so that a sidewall 200S of the formed light-absorbing layer 200 may have the following specific profile to improve the stability of the light-absorbing layer 200, which will not be described in detail here. In the embodiment, the material of the light-absorbing layer 200 also includes a photoresist composition, wherein reference may be made to the above embodiment for examples of the photoresist composition, which will not be described again here. Since the material of the light-absorbing layer 200 includes the photochromic material and the photoresist composition, the optical density value of the light-absorbing layer 200 may be between 1.5 and 5 (or 2 and 5). That is, the light-absorbing layer 200 of the embodiment can have an improved light-shielding effect.

In the embodiment, the light-absorbing layer 200 includes multiple openings 200_OP, wherein the openings 200_OP of the light-absorbing layer 200 are formed through performing the above exposure process and patterning process.

Further, please refer to FIG. 2A to FIG. 2D. FIG. 2A to FIG. 2D individually show the openings 200_OP of the light-absorbing layer 200 formed through performing the exposure process on the photoresist under conditions of the exposure energy being 200 mJ/cm², 250 mJ/cm², 300 mJ/cm², and 350 mJ/cm².

In some embodiments, in the cross-sectional views shown in FIG. 2A to FIG. 2D, the profile of the sidewall 200S of the opening 200_OP has at least one arc-shaped edge. In the embodiment, the sidewall 200S of the opening 200_OP of the light-absorbing layer 200 is in the form of a cubic plane curve and has an inflection point. In detail, the sidewall 200S of the opening 200_OP of the light-absorbing layer 200 has, for example, a first arc-shaped edge 200R1 and a second arc-shaped edge 200R2, wherein the first arc-shaped edge 200R1 and the second arc-shaped edge 200R2 are, for example, connected to each other and individually have a convex point 200B and a concave point 200C, and there is an inflection point 2001 between the first arc-shaped edge 200R1 and the second arc-shaped edge 200R2.

In some embodiments, in the cross-sectional views shown in FIG. 2A to FIG. 2D, an inclination angle θ between an extension line 200EL of the sidewall 200S of the opening 200OP and a horizontal line is between 75 degrees and 105 degrees. In the embodiment, the extension line 200EL of the sidewall 200S is defined as a straight line obtained by extending 1 μm from the inflection point 2001 toward the top view direction z of the electronic device 10a and an opposite direction thereof, respectively finding two points d1 and d2, and then connecting the point d1 and the point d2. In addition, the horizontal line is, for example, in a direction perpendicular to the top view direction z of the electronic device 10a.

In the embodiment, a position (height H1) of the inflection point 2001 is located at 0.4 times to 0.6 times a height H of the light-absorbing layer 200, a position (height H2) of the convex point 200B is located at 0.5 times to 0.9 times the height H of the light-absorbing layer 200, and a position (height H3) of the concave point 200C is located at 0.1 times to 0.4 times the height H of the light-absorbing layer 200. In some embodiments, the height H of the light-absorbing layer 200 is between 7.5 m and 10.5 m, but the disclosure is not limited thereto. In other embodiments, the height H of the light-absorbing layer 200 is between 5 m and 10.5 m, but the disclosure is not limited thereto. It should be noted that the height H of the light-absorbing layer 200 is, for example, a height measured from the bottommost part of the light-absorbing layer 200 to the topmost part of the light-absorbing layer 200.

In other embodiments, the profile of the sidewall 200S of the opening 200OP may be composed of more than 3 sets of slopes and more than 2 sets of included angles. In detail, the cross-sectional view shown in FIG. 2E shows that the profile of the sidewall 200S of the opening 200_OP is composed of 5 sets of slopes S′₁, S′₂, S′₃, S′₄, and S′_{5 4} and 4 sets of included angles C′₁, C′₂, C′₃, and C′₄, wherein the included angle C′₁ is an angle between the slope S′₁ and the slope S′₂, the included angle C′₂ is an angle between the slope S′₂ and the slope S′₃, the included angle C′₃ is an angle between the slope S′₃ and the slope S′₄, and the included angle C′₄ is an angle between the slope S′₄ and the slope S′₅, but the disclosure is not limited thereto.

The electronic component 300 is, for example, disposed in the opening 200_OP of the light-absorbing layer 200 and electrically connected to the circuit substrate 100. In some embodiments, the electronic component 300 includes a light-emitting element, which may include a diode, an organic light-emitting diode (OLED), an inorganic light-emitting diode, such as a mini LED or a micro LED, quantum dot (QD), a QDLED, fluorescence, phosphor, other suitable materials, or a combination of the above materials. For example, the electronic component 300 may include a light-emitting diode. In the embodiment, the electronic component 300 is a flip chip micro LED, but the disclosure is not limited thereto. The electronic component 300 may include, for example, an electrode 310, wherein the electronic component 300 is bonded to the bonding pad PAD through the electrode 310, so that the electronic component 300 may be electrically connected to the thin film transistor of the circuit substrate 100 through the bonding pad PAD, but the disclosure is not limited thereto. In some embodiments, the bonding pad PAD may include a convex block PAD1 and a solder PAD2, wherein the solder PAD2 is disposed on the convex block PAD1, and at least part of the convex block PAD1 is electrically connected to the connecting structure CS. Based on this, the electronic component 300 may be electrically connected to the thin film transistor of the circuit substrate 100 through the bonding pad PAD.

The material of the convex block PAD1 may include, for example, a metal or an alloy. For example, the material of the convex block PAD1 may be an alloy of gold and nickel, which may be formed through an electroless nickel immersion gold (ENIG) process, but the disclosure is not limited thereto. The material of the solder PAD2 may include, for example, tin, but the disclosure is not limited thereto. The electronic component 300 may also be a vertical micro LED. In the embodiment, the electronic component 300 of the embodiment may include the red light-emitting diode 300R, the green light-emitting diode 300G, and the blue light-emitting diode 300B, but the disclosure is not limited thereto. The electronic component 300 may, for example, be electrically connected to the thin film transistor (not shown) in the circuit substrate 100 to emit light through the control of the thin film transistor. In some embodiments, the electronic component 300 may emit various suitable color lights (for example, color lights such as red light, green light, blue light, and white light), infrared (IR) light, or ultraviolet (UV) light, but the disclosure is not limited thereto.

In the embodiment, the electronic device 10a also includes the opposing substrate 400a, the adhesion layer AL, and the filling layer FL.

The opposing substrate 400a is, for example, disposed opposing the circuit substrate 100. The opposing substrate 400a may include, for example, anti-reflective, dustproof, anti-scratch, and anti-water vapor intrusion effects to reduce the impact of the external environment on components inside the electronic device 10a and may, for example, be light-transmissive. In some embodiments, the material of the opposing substrate 400a may include glass, wherein the type and the composition of the glass are not particularly limited, and the glass may be, for example, aluminosilicate glass, lithium aluminosilicate glass, soda-lime silicate glass, aluminosilicate glass, quartz glass, or other light-transmissive glass, but the disclosure is not limited thereto. In other embodiments, the material of the opposing substrate 400a may include an organic material, which may be, for example, a resin, acrylic, polyimide, or other suitable organic materials. In other embodiments, the opposing substrate 400a may include a Bragg reflective layer to achieve an anti-reflective effect. In other embodiments, the opposing substrate 400a may include an anti-fouling layer. The anti-fouling layer may include, for example, a fluorine-containing compound.

The adhesion layer AL is, for example, disposed between the circuit substrate 100 and the opposing substrate 400a in the top view direction z of the electronic device 10a, so that the circuit substrate 100 and the opposing substrate 400a are adhered to each other. In some embodiments, the material of the adhesion layer AL may include an optical clear adhesive (OCA) or an optical clear resin (OCR), which includes, for example, an acrylic resin, a silicone resin, an epoxy resin, other suitable materials, or a combination of the above materials, but the disclosure is not limited thereto. In some embodiments, in addition to the function of adhering the circuit substrate 100 and the opposing substrate 400a to each other, the adhesion layer AL may also have water and oxygen blocking characteristics, protective characteristics, or other characteristics, but the disclosure is not limited thereto.

The filling layer FL is, for example, disposed in the opening 200_OP of the light-absorbing layer 200, and is, for example, disposed adjacent to or surrounding the electronic component 300. The filling layer FL may be used, for example, to fix or protect the electronic component 300. In some embodiments, the filling layer FL may include a transparent material, a non-transparent material, or a combination thereof. For example, the material of the filling layer FL may include an epoxy resin, acrylic, other suitable materials, or a combination thereof, but the disclosure is not limited thereto.

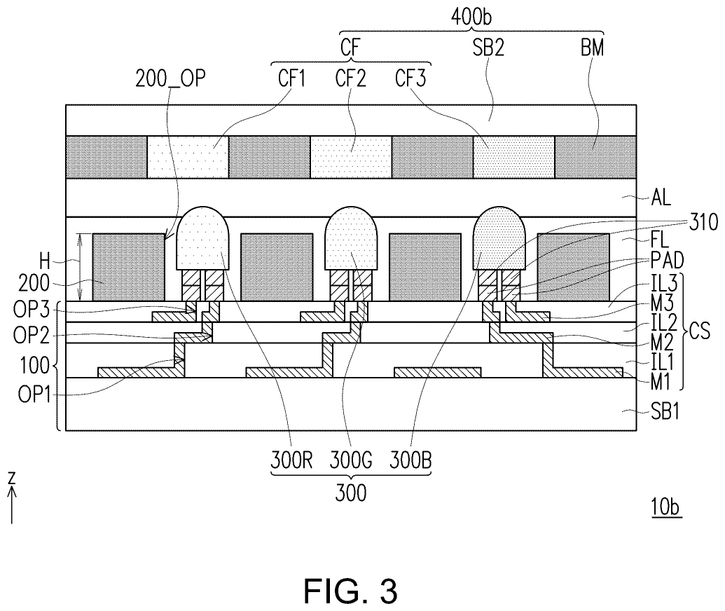

FIG. 3 is a partial cross-sectional schematic view of an electronic device according to the second embodiment of the disclosure. It should be noted that the embodiment of FIG. 3 may continue to use the reference numerals and some content of the embodiment of FIG. 1, wherein the same or similar numerals are used to represent the same or similar components, and the description of the same technical content is omitted.

Please refer to FIG. 3. In the embodiment, an electronic device 10b has a double-board structure. In detail, the main difference between the electronic device 10b and the electronic device 10a of the embodiment lies in the structure of an opposing substrate 400b.

In the embodiment, the electronic device 10b includes the circuit substrate 100, the light-absorbing layer 200, the electronic component 300, the opposing substrate 400b, the adhesion layer AL, and the filling layer FL, wherein reference may be made to the above embodiment for the description of the circuit substrate 100, the light-absorbing layer 200, the electronic component 300, the adhesion layer AL, and the filling layer FL, which will not be described again here.

The opposing substrate 400b is, for example, disposed opposing the circuit substrate 100 and may include, for example, a substrate SB2, a light-shielding pattern BM, and a color filter CF.

The material of the substrate SB2 may be, for example, the same as or similar to the material of the substrate SB1 of the circuit substrate 100, which will not be described again here.

The light-shielding pattern BM and the color filter CF are, for example, disposed on the substrate SB2. In some embodiments, the light-shielding pattern BM and the color filter CF are individually disposed on a surface of the substrate SB2 facing the circuit substrate 100, but the disclosure is not limited thereto. In the embodiment, the light-shielding pattern BM is, for example, adjacent to or surrounding the color filter CF. For example, the light-shielding pattern BM may have multiple openings to form a grid structure, wherein the color filter CF may be disposed in the corresponding opening, but the disclosure is not limited thereto. The material of the light-shielding pattern BM may include, for example, a black resin, a black photoresist, a metal, or a combination thereof, but the disclosure is not limited thereto. Based on this, the light-shielding pattern BM may be used, for example, to shield components and wiring inside the electronic device 10b that are not intended to be seen by a user, so as to improve the display effect of the electronic device 10b. The color filter CF may include, for example, a red filter pattern, a green filter pattern, a blue filter pattern, filter patterns of other colors, or a combination thereof, thereby enabling the electronic device 10b to reduce the reflection of ambient light to improve the contrast of the environment, but the disclosure is not limited thereto.

In summary, in the electronic device and the manufacturing method thereof provided by some embodiments of the disclosure, the light-absorbing layer with relatively low reflectivity and used to define the placement space of the electronic component may be formed using a relatively small number of processes, which can improve the process efficiency of the electronic device provided by the disclosure and/or reduce the process cost of the electronic device provided by the disclosure. Furthermore, through enabling the light-absorbing layer to include the photochromic material, the photosensitivity of the bottom portion of the light-absorbing layer can be enhanced using the discoloration mechanism of the photochromic material during the process of forming the light-absorbing layer, so that the light-absorbing layer can still maintain a structure with a relatively stable shape while having a desired thickness (the inclination angle between the extension line of the sidewall of the opening and the horizontal line is between 75 degrees and 105 degrees), thereby improving the reliability of the electronic device provided by the disclosure.

What is claimed is:

1. An electronic device, comprising:
a circuit substrate;
a light-absorbing layer, disposed on the circuit substrate, the light-absorbing layer comprising an opening; and
an electronic component, disposed in the opening and electrically connected to the circuit substrate,
wherein in a cross-sectional view, a profile of a sidewall of the opening has at least one arc-shaped edge, and an inclination angle between an extension line of the sidewall of the opening and a horizontal line is between 75 degrees and 105 degrees.

2. The electronic device according to claim 1, wherein the profile of the sidewall of the opening has a first arc-shaped edge and a second arc-shaped edge, and there is an inflection point between the first arc-shaped edge and the second arc-shaped edge.

3. The electronic device according to claim 2, wherein the inflection point is located at 0.4 to 0.6 times a height of the light-absorbing layer.

4. The electronic device according to claim 2, wherein the first arc-shaped edge has a convex point, and a position of the convex point is located at 0.5 to 0.9 times a height of the light-absorbing layer.

5. The electronic device according to claim 2, wherein the second arc-shaped edge has a concave point, and a position of the concave point is located at 0.1 to 0.4 times a height of the light-absorbing layer.

6. The electronic device according to claim 1, wherein an optical density value of the light-absorbing layer is between 1.5 and 5.

7. The electronic device according to claim 1, wherein the light-absorbing layer comprises a photochromic material.

8. The electronic device according to claim 1, wherein a height of the light-absorbing layer is between 7.5 m and 10.5 m.

9. The electronic device according to claim 1, wherein the circuit substrate comprises a bonding pad, the electronic component comprises an electrode, and the electronic component is connected to the bonding pad through the electrode.

10. The electronic device according to claim 1, wherein the electronic component is a red light-emitting diode, a green light-emitting diode, or a blue light-emitting diode.

11. A manufacturing method of an electronic device, comprising:
providing a circuit substrate;
coating a photoresist on the circuit substrate;
measuring a first optical eigenvalue of the photoresist before exposure;
exposing the photoresist;
measuring a second optical eigenvalue of the photoresist after exposure; and
patterning the photoresist, so that the photoresist forms an opening,
wherein a time for patterning the photoresist is adjusted according to a difference between the first optical eigenvalue and the second optical eigenvalue.

12. The manufacturing method of the electronic device according to claim 11, wherein the first optical eigenvalue and the second optical eigenvalue are respectively a first brightness value and a second brightness value.

13. The manufacturing method of the electronic device according to claim 11, further comprising:
curing the photoresist to form a light-absorbing layer.

14. The manufacturing method of the electronic device according to claim 11, further comprising:
disposing the electronic component in the opening.

15. The manufacturing method of the electronic device according to claim 11, wherein an optical density value of the photoresist is between 1.5 and 5.

16. The manufacturing method of the electronic device according to claim 11, wherein the photoresist comprises a photochromic material.

17. The manufacturing method of the electronic device according to claim 11, wherein a thickness of the photoresist is between 7.5 m and 10.5 m.

18. The manufacturing method of the electronic device according to claim 11, wherein the difference between the first optical eigenvalue and the second optical eigenvalue is related to an exposure energy in the exposure step.

19. The manufacturing method of the electronic device according to claim 11, wherein the step of patterning the photoresist is performed through a development process.

20. The manufacturing method of the electronic device according to claim 19, wherein the difference between the first optical eigenvalue and the second optical eigenvalue is compared with a preset value to determine a time of the development process.
